(19) United States
(12) Patent Application Publication
(10) Pub. No.: US 2008/0106868 A1
(43) Pub. Date: May 8, 2008

(54) THERMAL INTERFACE MATERIAL VOLUME BETWEEN THERMAL CONDUCTING MEMBERS

(75) Inventors: Shawn P. Hoss, Round Rock, TX (US); Paul T. Artman, Austin, TX (US)

Correspondence Address: HAYNES AND BOONE, LLP, 901 Main Street, Suite 3100, Dallas, TX, 75202, US

(73) Assignee: DELL PRODUCTS L.P., Round Rock, TX (US)

(21) Appl. No.: 11/556,272

(22) Filed: Nov. 3, 2006

(51) Int. Cl. H05K 7/20

(52) U.S. Cl. 361/704

(57) ABSTRACT

A heat dissipation apparatus includes a first thermal conducting member including a first thermal transfer surface. A second thermal conducting member including a second thermal transfer surface that is located adjacent the first thermal transfer surface. A thermal interface material engages the first thermal transfer surface and the second thermal transfer surface. A channel is defined adjacent the first thermal transfer surface and the second thermal transfer surface, whereby an excess of the thermal interface material is located in the channel. The first thermal conducting member may be thermally coupled to an information handling system processor and the channel may prevent the thermal interface material from engaging sensitive surfaces adjacent the processor.

### BACKGROUND

The present disclosure relates generally to information handling systems, and more particularly to a thermal interface material volume between thermal conducting members in an information handling system chassis.

As the value and use of information continues to increase, individuals and businesses seek additional ways to process and store information. One option is an information handling system (IHS). An IHS generally processes, compiles, stores, and/or communicates information or data for business, personal, or other purposes. Because technology and information handling needs and requirements may vary between different applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Typically IHSs include a plurality of thermal conducting members such as, for example, processors, integrated heat spreaders, heat sinks, heat transfer dies, and a variety of other thermal conducting materials known in the art. As the heat production of thermal conducting members such as processors increases, the transfer of heat between thermal conducting members such as the processor, an integrated heat spreader, a heat transfer die, and/or a heat sink raises a number of issues.

Conventionally, a thermal interface material such as, for example, a thermal grease, a phase change thermal interface material, and/or a variety of other thermal interface materials known in the art, is used between a plurality of thermal conducting members such as, for example, a processor and a heat sink, an integrated heat spreader and a heat sink, a heat transfer die and a heat sink, and/or a pair of heat sinks, in order to fill air gaps in the thermal conduction path between the two thermal conducting members. It is optimal to apply an amount of thermal interface material to the interface surfaces between the thermal conducting members such that the thermal interface material engages approximately 100% of the interfaces surfaces between the thermal conducting members and completely occupies an interface volume between the thermal conducting members. However, when pressure is applied to engage the thermal conducting members the thermal interface material and then heat is transferred between the thermal conducting members, the thermal interface material thins and spreads across the interface surfaces between the thermal conducting members. This can cause the thermal interface material to flow out of the interface volume between the thermal conducting members and migrate onto, for example, a silicon substrate or a printed circuit board that the thermal conducting members are coupled to. This phenomenon is known as “pump out” and is accelerated by expansion and contraction of the thermal conducting members during heating and cooling cycles, which results in the loss of the thermal interface material from the interface volume between the thermal conducting members. This can be particularly problematic in some chipsets and processors that include power input pads located adjacent the chipset or processor on the base substrate, as the thermal interface material can migrate out of the interface volume between the thermal conducting members and onto the power input pads, resulting in excessive heating and part failure at the power interconnect.

Accordingly, it would be desirable to provide a thermal interface material volume between thermal conducting members absent the disadvantages found in the prior methods discussed above.

### SUMMARY

According to one embodiment, a heat dissipation apparatus includes a first thermal conducting member comprising a first thermal transfer surface, a second thermal conducting member comprising a second thermal transfer surface that is located adjacent the first thermal transfer surface, a thermal interface material engaging the first thermal transfer surface and the second thermal transfer surface, and a channel defined adjacent the first thermal transfer surface and the second thermal transfer surface, whereby an excess of the thermal interface material is located in the channel.

### BRIEF DESCRIPTION OF THE DRAWINGS

FIG. 1 is a schematic view illustrating an embodiment of an IHS.

FIG. 2 is a perspective view illustrating an embodiment of a board.

FIG. 3 is a perspective view illustrating an embodiment of a second thermal conducting member used with the board of FIG. 2.

FIG. 4a is a flow chart illustrating a method for housing excess thermal interface material in a heat dissipation system.

FIG. 4b is a perspective view illustrating the second thermal conducting member of FIG. 3 being coupled to the board of FIG. 2 including a thermal interface material.

FIG. 4c is a cross sectional view illustrating the second thermal conducting member of FIG. 3 coupled to the board of FIG. 2 including a thermal interface material.

FIG. 5a is a perspective view illustrating an alternative embodiment of a board.

FIG. 5b is a perspective view illustrating the second thermal conducting member of FIG. 3 being coupled to the board of FIG. 5a including a thermal interface material.

FIG. 5c is a cross sectional view illustrating the second thermal conducting member of FIG. 3 coupled to the board of FIG. 5a including a thermal interface material.

FIG. 6a is a perspective view illustrating an alternative embodiment of a board.

FIG. 6b is a perspective view illustrating the second thermal conducting member of FIG. 3 being coupled to the board of FIG. 6a including a thermal interface material.

FIG. 6c is a cross sectional view illustrating the second thermal conducting member of FIG. 3 coupled to the board of FIG. 6a including a thermal interface material.

FIG. 7a is a perspective view illustrating an alternative embodiment of a board.

FIG. 7b is a perspective view illustrating an alternative embodiment of a second thermal conducting member used with the board of FIG. 7a.

FIG. 7c is a perspective view illustrating the second thermal conducting member of FIG. 7b being coupled to the board of FIG. 7a including a thermal interface material.

FIG. 7d is a cross sectional view illustrating the second thermal conducting member of

FIG. 7b coupled to the board of FIG. 7a including a thermal interface material.

FIG. 8a is a perspective view illustrating an alternative embodiment of a board.

FIG. 8b is a perspective view illustrating an alternative embodiment of a second thermal conducting member used with the board of FIG. 8a.

FIG. 8c is a perspective view illustrating the second thermal conducting member of FIG. 8b being coupled to the board of FIG. 8a including a thermal interface material.

FIG. 8d is a cross sectional view illustrating the second thermal conducting member of FIG. 8b coupled to the board of FIG. 8a including a thermal interface material.

### DETAILED DESCRIPTION

For purposes of this disclosure, an IHS may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, an IHS may be a personal computer, a PDA, a consumer electronic device, a network server or storage device, a switch router or other network communication device, or any other suitable device and may vary in size, shape, performance, functionality, and price. The IHS may include memory, one or more processing resources such as a central processing unit (CPU) or hardware or software control logic. Additional components of the IHS may include one or more storage devices, one or more communications ports for communicating with external devices as well as various input and output (I/O) devices, such as a keyboard, a mouse, and a video display. The IHS may also include one or more buses operable to transmit communications between the various hardware components.

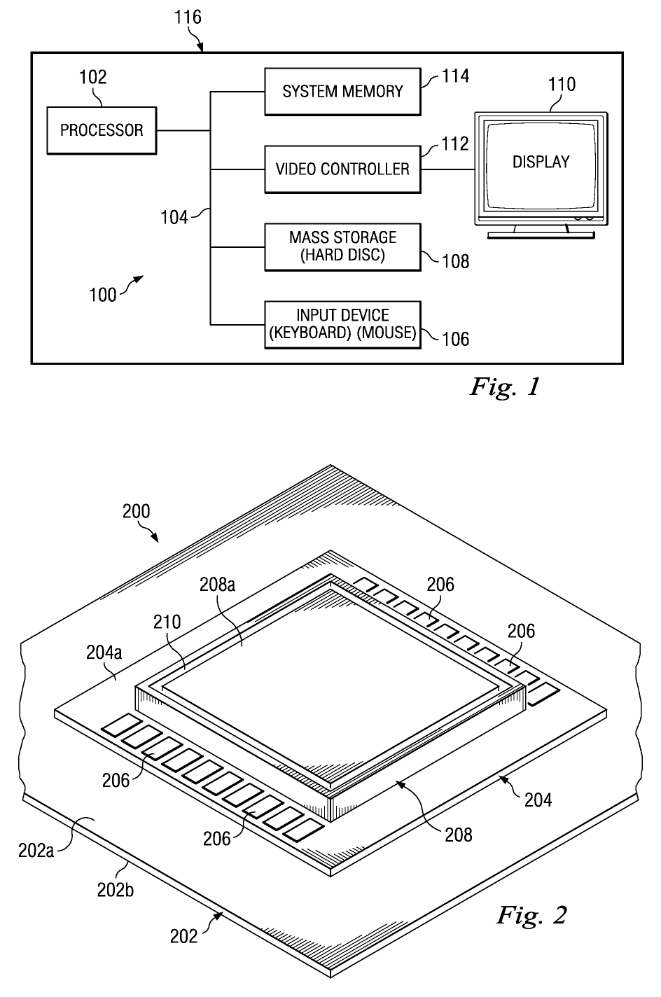

In one embodiment, IHS 100, FIG. 1, includes a processor 102, which is connected to a bus 104. Bus 104 serves as a connection between processor 102 and other components of computer system 100. An input device 106 is coupled to processor 102 to provide input to processor 102. Examples of input devices include keyboards, touchscreens, and pointing devices such as mouses, trackballs and trackpads. Programs and data are stored on a mass storage device 108, which is coupled to processor 102. Mass storage devices include such devices as hard disks, optical disks, magneto-optical drives, floppy drives and the like. IHS 100 further includes a display 110, which is coupled to processor 102 by a video controller 112. A system memory 114 is coupled to processor 102 to provide the processor with fast storage to facilitate execution of computer programs by processor 102. In an embodiment, a chassis 116 houses some or all of the components of IHS 100. It should be understood that other buses and intermediate circuits can be deployed between the components described above and processor 102 to facilitate interconnection between the components and the processor 102.

Referring now to FIG. 2, a board 200 is illustrated. The board 200 may be housed in an IHS chassis such as, for example, the IHS chassis 116, described above with reference to FIG. 1, and may include some or all of the components of the IHS 100, described above with reference to FIG. 1. The board 200 includes a base 202 having a top surface 202a and the bottom surface 202b located opposite the top surface 202a. A heat producing component 204 such as, for example, a processor, including a sensitive top surface 204a is mounted to the top surface 202a of the board 202. A plurality of electrical contacts 206 are located on the sensitive top surface 204a of the heat producing member 204. A first thermal conducting member 208 extends from the sensitive top surface 204a of the processor 204 and includes a first thermal transfer surface 208a. In an embodiment, the first thermal conducting member 208 may be, for example, a surface on a processor, an integrated heat spreader, a heat sink, or a variety of other thermal conducting members known in the art. A channel 210 is defined by the thermal conducting member 208 and located on the first thermal transfer surface 208a and adjacent the perimeter of the first thermal transfer surface 208a.

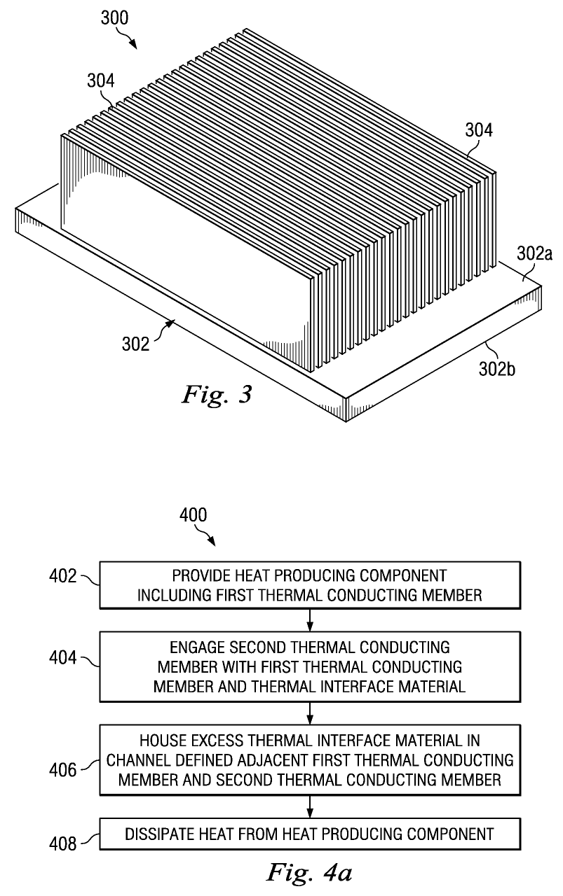

Referring now to FIG. 3, a second thermal conducting member 300 is illustrated. In an embodiment, the second thermal conducting member 300 is a heat sink. The second thermal conducting member 300 includes a base 302 having a top surface 302a and a second thermal transfer surface 302b located opposite the top surface 302a. A plurality of fins 304 extend from the top surface 302a of the base 302. In an embodiment, the second thermal conducting member 300 may include other heat dissipation components such as, for example, heat pipes, vapor chambers, and/or a variety of other heat dissipation components known in the art.

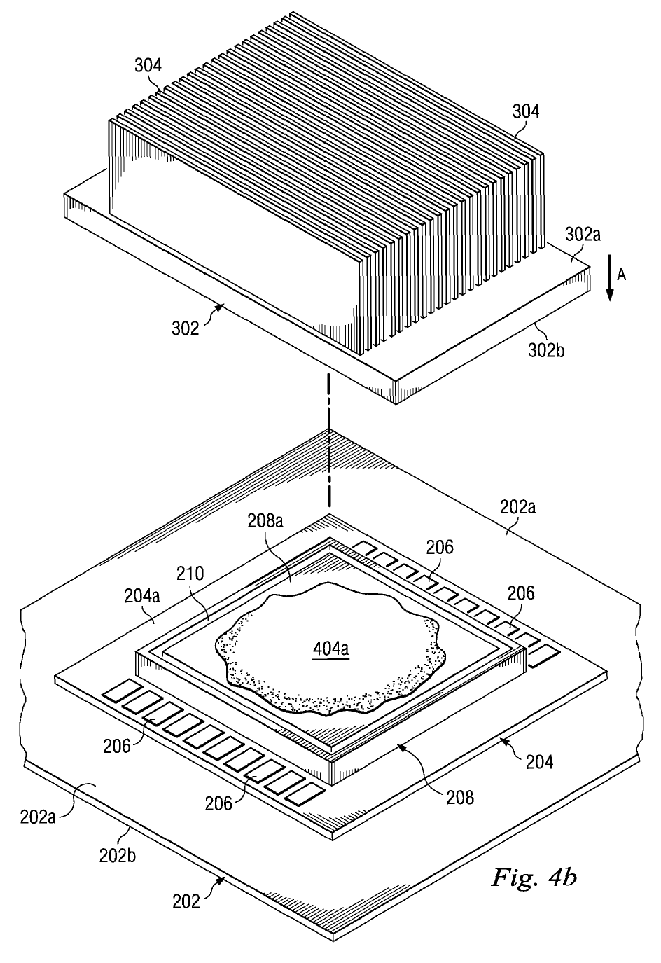

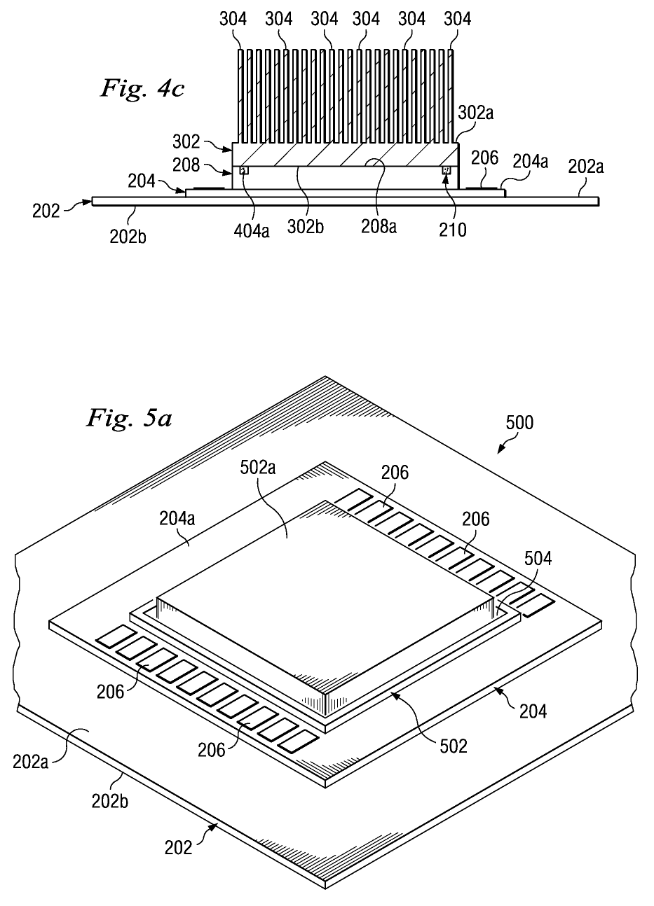

Referring now to FIGS. 4a, 4b and 4c, a method 400 for housing excess thermal interface material in a heat dissipation system is illustrated. In an embodiment, the board 200, described above with reference to FIG. 2, and the second thermal conducting member 300, described above with reference to FIG. 3, provide a heat dissipation system. The method 400 begins at step 402 where the heat producing component 204 including the first thermal conducting member 208 is provided. The method 400 then proceeds to step 404 where the second thermal conducting member 300 is engaged with the first thermal conducting member 208 and a thermal interface material. A thermal interface material 404a which may be, for example, a thermal grease, a phase change thermal interface material, and/or a variety of other thermal interface materials known in the art, is positioned on the first thermal transfer surface 208a such that the thermal interface material 404a is located within an area bounded by the channel 210, as illustrated in FIG. 4b. The second thermal conducting member 300 is then positioned adjacent the board 200 such that the second thermal transfer surface 302b on the second thermal conducting member 300 is located adjacent the first thermal transfer surface 208a on the first thermal conducting member 208, as illustrated in FIG. 4b. The second thermal conducting member 300 is then moved in a direction A such that the second thermal transfer surface 302b on the second thermal conducting member 300 engages the thermal interface material 404a. Continued movement of the second thermal conducting member 300 in the direction A causes the thermal interface material 404a to spread in the volume between the first thermal conducting member 208 and the second thermal conducting member 300 and engage both the first thermal transfer surface 208a on the first thermal conducting member 208 and the second thermal transfer surface 302b on the second thermal conducting member 300.

The method 400 then proceeds to step 406 where an excess of the thermal interface material 404a is housed in the channel 210 defined adjacent the first thermal conducting member 208 and the second thermal conducting member 300. It is optimal to apply an amount of thermal interface material 404a to the first thermal transfer surface 208a such that the thermal interface material 404a engages approximately 100% of the first thermal transfer surface 208a and completely occupies the volume between the first thermal conducting member 208 and the second thermal conducting member 300. In order to ensure approximately 100% engagement of the first thermal transfer surface 208a with the thermal interface material 404a, typically an excess of thermal interface material 404a over what is needed to achieve approximately 100% engagement is applied to the first thermal transfer surface 208a. As the thermal interface material 404a spreads in the volume between the first thermal conducting member 208 and the second thermal conducting member 300, the excess of thermal interface material 404a becomes housed in the channel 210, preventing the excess of thermal interface material 404a from migrating off of the first thermal transfer surface 208a and onto the sensitive top surface 204a and the electrical contacts 206, as illustrated in FIG. 4c. The method 400 then proceeds to step 408 where heat is dissipated from the heat producing component 204. The heat producing component 204 is operated and produces heat, which is conducted through the first thermal conducting member 208, the thermal interface material 404a, and the second thermal conducting member 300. The fins 304 on the second thermal conducting member 300 allow the heat to be dissipated to the ambient. Thus, an apparatus and method are provided that allow excess thermal interface material being used to help dissipate heat from a heat producing component to be housed such that the excess thermal interface material does not engage sensitive surfaces in the system that could cause failure in the system.

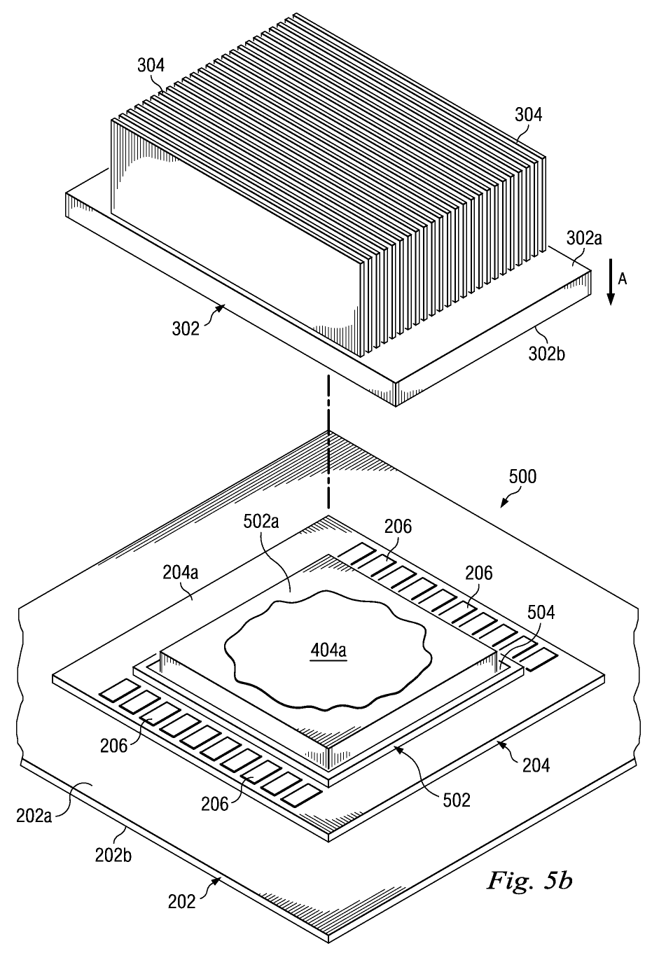

Referring now to FIGS. 5a, 5b and 5c, in an alternative embodiment, a board 500 is illustrated which is substantially similar in design and operation to the board 200, described above with reference to FIGS. 2, 4a, 4b and 4c, with the provision of a first thermal conducting member 502 replacing the first thermal conducting member 208. The first thermal conducting member 502 includes a first thermal transfer surface 502a and defines a channel 504 that is located adjacent the first thermal transfer surface 502a and about the perimeter of the first thermal transfer surface 502a, as illustrated in FIG. 5a. In operation, the board 500 may be used in place of the board 200 in the method 400. For example, the method 400 begins at step 402 where the heat producing component 204 including the first thermal conducting member 502 is provided. The method 400 then proceeds to step 404 where the second thermal conducting member 300 is engaged with the first thermal conducting member 502 and a thermal interface material. A thermal interface material 404a which may be, for example, a thermal grease, a phase change thermal interface material, and/or a variety of other thermal interface materials known in the art, is positioned on the first thermal transfer surface 502a, as illustrated in FIG. 5b. The second thermal conducting member 300 is then positioned adjacent the board 500 such that the second thermal transfer surface 302b on the second thermal conducting member 300 is located adjacent the first thermal transfer surface 502a on the first thermal conducting member 502, as illustrated in FIG. 5b. The second thermal conducting member 300 is then moved in a direction A such that the second thermal transfer surface 302b on the second thermal conducting member 300 engages the thermal interface material 404a. Continued movement of the second thermal conducting member 300 in the direction A causes the thermal interface material 404a to spread in the volume between the first thermal conducting member 502 and the second thermal conducting member 300 and engage both the first thermal transfer surface 502a on the first thermal conducting member 502 and the second thermal transfer surface 302b on the second thermal conducting member 300.

The method 400 then proceeds to step 406 where an excess of the thermal interface material 404a is housed in the channel 504 defined adjacent the first thermal conducting member 502 and the second thermal conducting member 300. It is optimal to apply an amount of thermal interface material 404a to the first thermal transfer surface 502a such that the thermal interface material 404a engages approximately 100% of the first thermal transfer surface 502a and completely occupies the volume between the first thermal conducting member 502 and the second thermal conducting member 300. In order to ensure approximately 100% engagement of the first thermal transfer surface 502a with the thermal interface material 404a, typically an excess of thermal interface material 404a over what is needed to achieve approximately 100% engagement is applied to the first thermal transfer surface 502a. As the thermal interface material 404a spreads in the volume between the first thermal conducting member 502 and the second thermal conducting member 300, the excess of thermal interface material 404a becomes housed in the channel 504, preventing the excess of thermal interface material 404a from migrating off of the first thermal transfer surface 502a and onto the sensitive top surface 204a and the electrical contacts 206, as illustrated in FIG. 5c. The method 400 then proceeds to step 408 where heat is dissipated from the heat producing component 204. The heat producing component 204 is operated and produces heat, which is conducted through the first thermal conducting member 502, the thermal interface material 404a, and the second thermal conducting member 300. The fins 304 on the second thermal conducting member 300 allow the heat to be dissipated to the ambient. Thus, an apparatus and method are provided that allow excess thermal interface material being used to help dissipate heat from a heat producing component to be housed such that the excess thermal interface material does not engage sensitive surfaces in the system that could cause failure in the system.

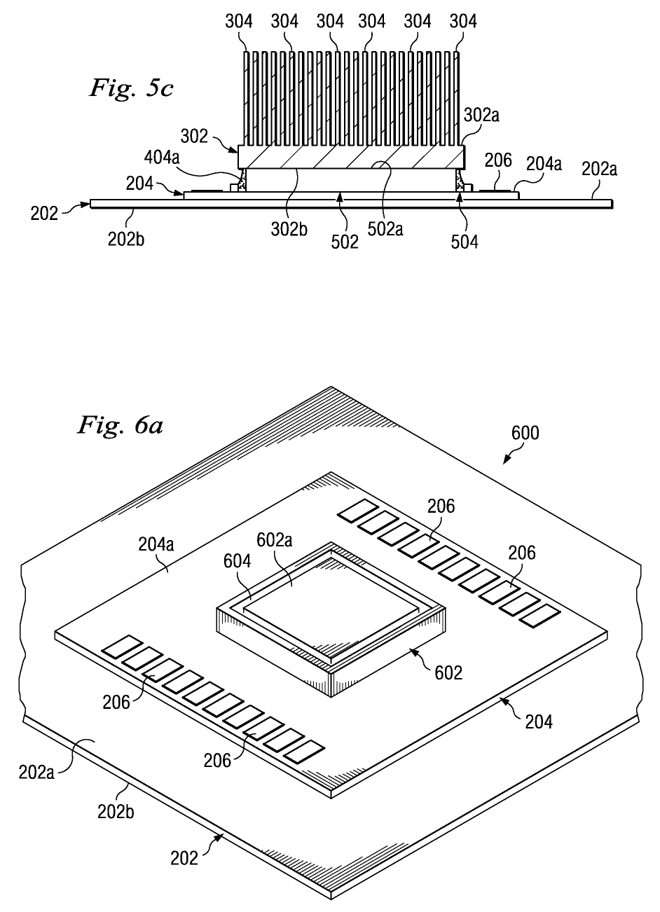

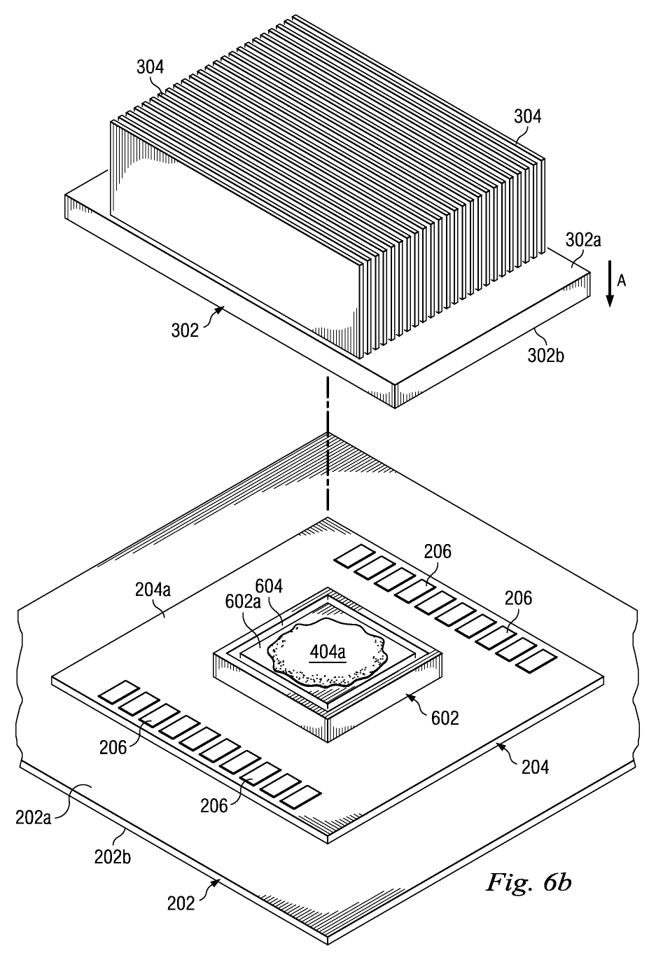

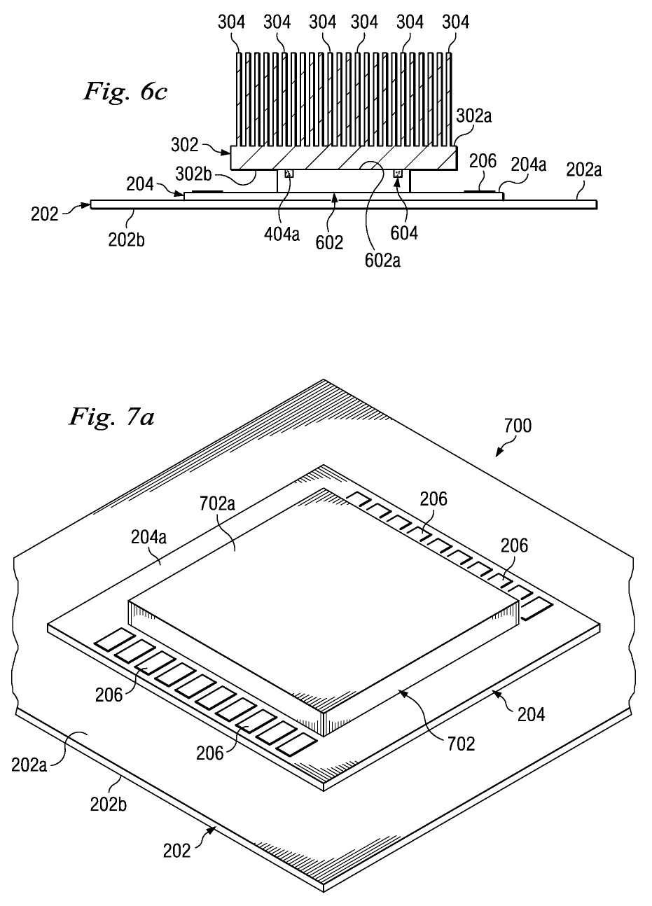

Referring now to FIGS. 6a, 6b and 6c, in an alternative embodiment, a board 600 is illustrated which is substantially similar in design and operation to the board 200, described above with reference to FIGS. 2, 4a, 4b and 4c, with the provision of a first thermal conducting member 602 replacing the first thermal conducting member 208. In an embodiment, the first thermal conducting member 602 may be, for example, a die that is coupled to the heat producing component 204. The first thermal conducting member 602 includes a first thermal transfer surface 602a and defines a channel 604 that is located on the first thermal transfer surface 602a and adjacent the perimeter of the first thermal transfer surface 602a, as illustrated in FIG. 6a. In operation, the board 600 may be used in place of the board 200 in the method 400. For example, the method 400 begins at step 402 where the heat producing component 204 including the first thermal conducting member 602 is provided. The method 400 then proceeds to step 404 where the second thermal conducting member 300 is engaged with the first thermal conducting member 602 and a thermal interface material. A thermal interface material 404a which may be, for example, a thermal grease, a phase change thermal interface material, and/or a variety of other thermal interface materials known in the art, is positioned on the first thermal transfer surface 602a such that the thermal interface material 404a is located within an area bounded by the channel 604, as illustrated in FIG. 6b. The second thermal conducting member 300 is then positioned adjacent the board 600 such that the second thermal transfer surface 302b on the second thermal conducting member 300 is located adjacent the first thermal transfer surface 602a on the first thermal conducting member 602, as illustrated in FIG. 6b. The second thermal conducting member 300 is then moved in a direction A such that the second thermal transfer surface 302b on the second thermal conducting member 300 engages the thermal interface material 404a. Continued movement of the second thermal conducting member 300 in the direction A causes the thermal interface material 404a to spread in the volume between the first thermal conducting member 602 and the second thermal conducting member 300 and engage both the first thermal transfer surface 602a on the first thermal conducting member 602 and the second thermal transfer surface 302b on the second thermal conducting member 300.

The method 400 then proceeds to step 406 where an excess of the thermal interface material 404a is housed in the channel 604 defined adjacent the first thermal conducting member 602 and the second thermal conducting member 300. It is optimal to apply an amount of thermal interface material 404a to the first thermal transfer surface 602a such that the thermal interface material 404a engages approximately 100% of the first thermal transfer surface 602a and completely occupies the volume between the first thermal conducting member 602 and the second thermal conducting member 300. In order to ensure approximately 100% engagement of the first thermal transfer surface 602a with the thermal interface material 404a, typically an excess of thermal interface material 404a over what is needed to achieve approximately 100% engagement is applied to the first thermal transfer surface 602a. As the thermal interface material 404a spreads in the volume between the first thermal conducting member 602 and the second thermal conducting member 300, the excess of thermal interface material 404a becomes housed in the channel 604, preventing the excess of thermal interface material 404a from migrating off of the first thermal transfer surface 602a and onto the sensitive top surface 204a and the electrical contacts 206. The method 400 then proceeds to step 408 where heat is dissipated from the heat producing component 204. The heat producing component 204 is operated and produces heat, which is conducted through the first thermal conducting member 602, the thermal interface material 404a, and the second thermal conducting member 300. The fins 304 on the second thermal conducting member 300 allow the heat to be dissipated to the ambient. Thus, an apparatus and method are provided that allow excess thermal interface material being used to help dissipate heat from a heat producing component to be housed such that the excess thermal interface material does not engage sensitive surfaces in the system that could cause failure in the system.

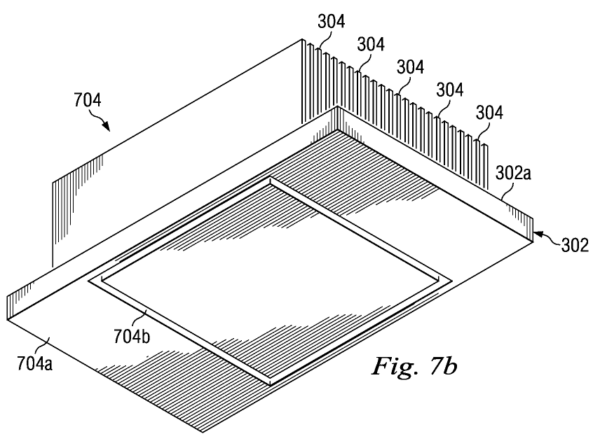

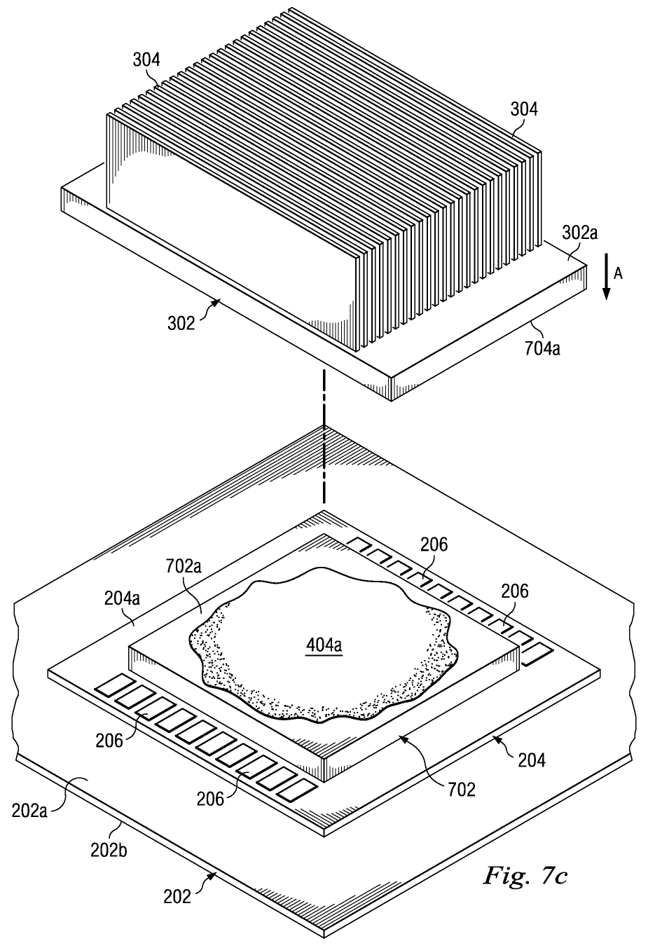

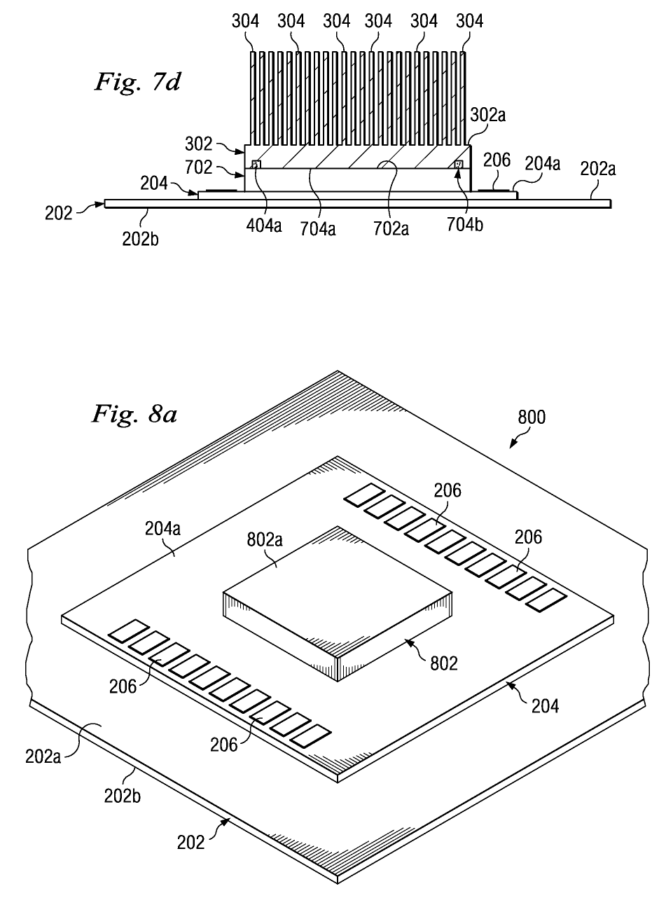

Referring now to FIGS. 7a, 7b, 7c, and 7d, in an alternative embodiment, a board 700 and a second thermal conducting member 704 are illustrated which are substantially similar in design and operation to the board 200 and the second thermal conducting member 300, described above with reference to FIGS. 2, 3, 4a, 4b and 4c, with the provision of a first thermal conducting member 702 replacing the first thermal conducting member 208 on the board 200 and a second thermal transfer surface 704a replacing the second thermal transfer surface 302b on the second thermal conducting member 300. The first thermal conducting member 702 includes a first thermal transfer surface 702a without the channel 210 of the first thermal conducting member 208, as illustrated in FIG. 7a. The second thermal conducting member 704 defines a channel 704b located on the second thermal transfer surface 704a, as illustrated in FIG. 7b. In operation, the board 700 may be used in place of the board 200 in the method 400. For example, the method 400 begins at step 402 where the heat producing component 204 including the first thermal conducting member 702 is provided. The method 400 then proceeds to step 404 where the second thermal conducting member 704 is engaged with the first thermal conducting member 702 and a thermal interface material. A thermal interface material 404a which may be, for example, a thermal grease, a phase change thermal interface material, and/or a variety of other thermal interface materials known in the art, is positioned on the first thermal transfer surface 702a, as illustrated in FIG. 7c. The second thermal conducting member 704 is then positioned adjacent the board 700 such that the second thermal transfer surface 704a on the second thermal conducting member 704 is located adjacent the first thermal transfer surface 702a on the first thermal conducting member 702, as illustrated in FIG. 7c. The second thermal conducting member 704 is then moved in a direction A such that the second thermal transfer surface 704a on the second thermal conducting member 704 engages the thermal interface material 404a. Continued movement of the second thermal conducting member 704 in the direction A causes the thermal interface material 404a to spread in the volume between the first thermal conducting member 702 and the second thermal conducting member 704 and engage both the first thermal transfer surface 702a on the first thermal conducting member 702 and the second thermal transfer surface 704a on the second thermal conducting member 704.

The method 400 then proceeds to step 406 where an excess of the thermal interface material 404a is housed in the channel 704b defined adjacent the first thermal conducting member 702 and the second thermal conducting member 704. It is optimal to apply an amount of thermal interface material 404a to the first thermal transfer surface 702a such that the thermal interface material 404a engages approximately 100% of the first thermal transfer surface 208a and completely occupies the volume between the first thermal conducting member 702 and the second thermal conducting member 704. In order to ensure approximately 100% engagement of the first thermal transfer surface 702a with the thermal interface material 404a, typically an excess of thermal interface material 404a over what is needed to achieve approximately 100% engagement is applied to the first thermal transfer surface 702a. As the thermal interface material 404a spreads in the volume between the first thermal conducting member 702 and the second thermal conducting member 704, the excess of thermal interface material 404a becomes housed in the channel 704b, preventing the excess of thermal interface material 404a from migrating off of the first thermal transfer surface 702a and onto the sensitive top surface 204a and the electrical contacts 206, as illustrated in FIG. 7d. The method 400 then proceeds to step 408 where heat is dissipated from the heat producing component 204. The heat producing component 204 is operated and produces heat, which is conducted through the first thermal conducting member 702, the thermal interface material 404a, and the second thermal conducting member 704. The fins 304 on the second thermal conducting member 704 allow the heat to be dissipated to the ambient. Thus, an apparatus and method are provided that allow excess thermal interface material being used to help dissipate heat from a heat producing component to be housed such that the excess thermal interface material does not engage sensitive surfaces in the system that could cause failure in the system.

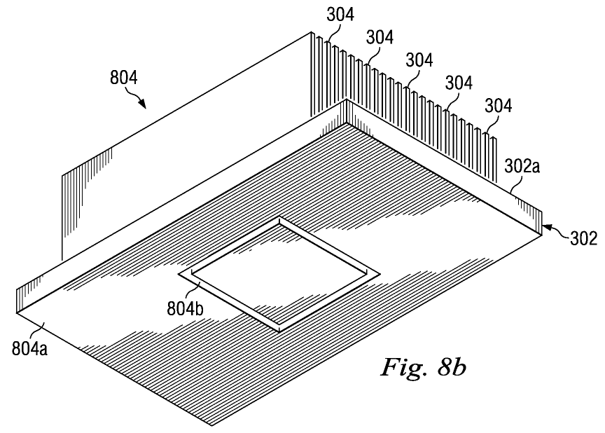

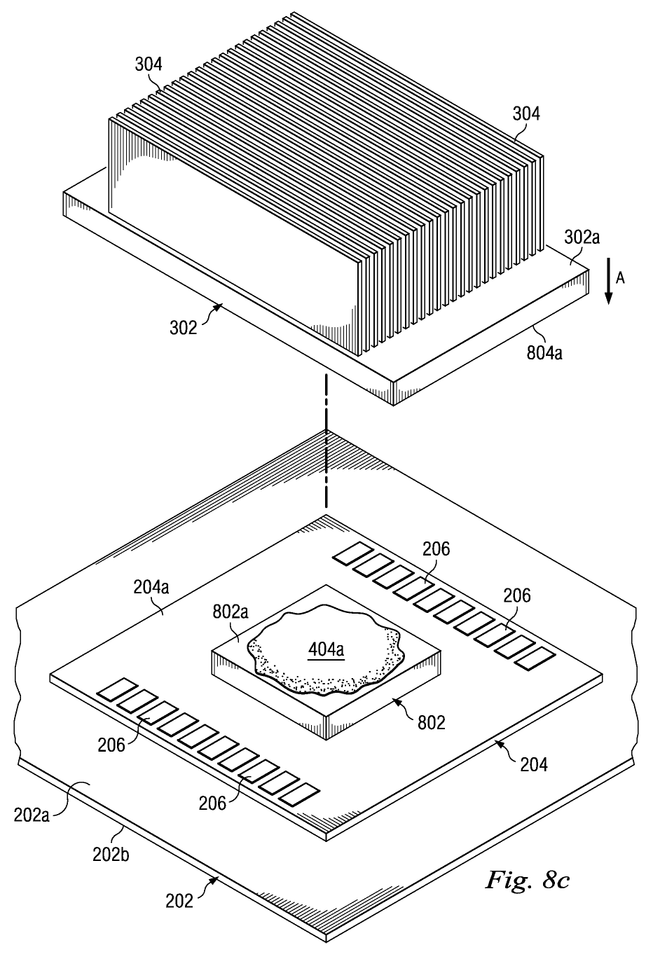

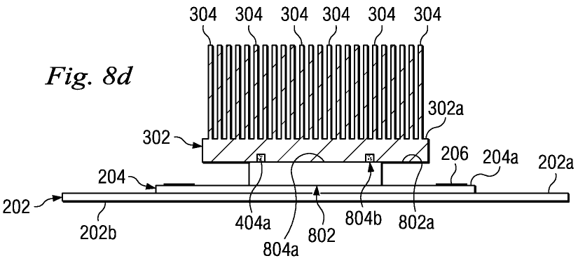

Referring now to FIGS. 8a, 8b, 8c and 8d, in an alternative embodiment, a board 800 and a second thermal conducting member 804 are illustrated which are substantially similar in design and operation to the board 600 and the second thermal conducting member 300, described above with reference to FIGS. 3, 4a, 4b, 4c, 6a, 6b and 6c with the provision of a first thermal conducting member 802 replacing the first thermal conducting member 602 on the board 600 and a second thermal transfer surface 804a replacing the second thermal transfer surface 302b on the second thermal conducting member 300. The first thermal conducting member 802 includes a first thermal transfer surface 802a without the channel 604 of the first thermal conducting member 602, as illustrated in FIG. 8a. The second thermal conducting member 804 defines a channel 804b located on the second thermal transfer surface 804a, as illustrated in FIG. 8b. In operation, the board 800 may be used in place of the board 200 in the method 400. For example, the method 400 begins at step 402 where the heat producing component 204 including the first thermal conducting member 802 is provided. The method 400 then proceeds to step 404 where the second thermal conducting member 804 is engaged with the first thermal conducting member 802 and a thermal interface material. A thermal interface material 404a which may be, for example, a thermal grease, a phase change thermal interface material, and/or a variety of other thermal interface materials known in the art, is positioned on the first thermal transfer surface 802a, as illustrated in FIG. 8c. The second thermal conducting member 804 is then positioned adjacent the board 800 such that the second thermal transfer surface 804a on the second thermal conducting member 804 is located adjacent the first thermal transfer surface 802a on the first thermal conducting member 802, as illustrated in FIG. 5c. The second thermal conducting member 804 is then moved in a direction A such that the second thermal transfer surface 804a on the second thermal conducting member 804 engages the thermal interface material 404a. Continued movement of the second thermal conducting member 804 in the direction A causes the thermal interface material 404a to spread in the volume between the first thermal conducting member 802 and the second thermal conducting member 804 and engage both the first thermal transfer surface 802a on the first thermal conducting member 802 and the second thermal transfer surface 804a on the second thermal conducting member 804.

The method 400 then proceeds to step 406 where an excess of the thermal interface material 404a is housed in the channel 804b defined adjacent the first thermal conducting member 802 and the second thermal conducting member 804. It is optimal to apply an amount of thermal interface material 404a to the first thermal transfer surface 802a such that the thermal interface material 404a engages approximately 100% of the first thermal transfer surface 802a and completely occupies the volume between the first thermal conducting member 802 and the second thermal conducting member 804. In order to ensure approximately 100% engagement of the first thermal transfer surface 802a with the thermal interface material 404a, typically an excess of thermal interface material 404a over what is needed to achieve approximately 100% engagement is applied to the first thermal transfer surface 802a. As the thermal interface material 404a spreads in the volume between the first thermal conducting member 802 and the second thermal conducting member 804, the excess of thermal interface material 404a becomes housed in the channel 804b, preventing the excess of thermal interface material 404a from migrating off of the first thermal transfer surface 802a and onto the sensitive top surface 204a and the electrical contacts 206, as illustrated in FIG. 8d. The method 400 then proceeds to step 408 where heat is dissipated from the heat producing component 204. The heat producing component 204 is operated and produces heat, which is conducted through the first thermal conducting member 802, the thermal interface material 404a, and the second thermal conducting member 804. The fins 304 on the second thermal conducting member 804 allow the heat to be dissipated to the ambient. Thus, an apparatus and method are provided that allow excess thermal interface material being used to help dissipate heat from a heat producing component to be housed such that the excess thermal interface material does not engage sensitive surfaces in the system that could cause failure in the system.

Although illustrative embodiments have been shown and described, a wide range of modification, change and substitution is contemplated in the foregoing disclosure and in some instances, some features of the embodiments may be employed without a corresponding use of other features. Accordingly, it is appropriate that the appended claims be construed broadly and in a manner consistent with the scope of the embodiments disclosed herein.

What is claimed is:

1. A heat dissipation apparatus, comprising:
a first thermal conducting member having a first thermal transfer surface;
a second thermal conducting member having a second thermal transfer surface that is located adjacent the first thermal transfer surface;
a thermal interface material engaging the first thermal transfer surface and the second thermal transfer surface; and
a channel defined adjacent the first thermal transfer surface and the second thermal transfer surface, whereby an excess of the thermal interface material is located in the channel.

2. The apparatus of claim 1, wherein the first thermal conducting member comprises a processor.

3. The apparatus of claim 1, wherein the first thermal conducting member comprises an integrated heat spreader.

4. The apparatus of claim 1, wherein the first thermal conducting member comprises a die.

5. The apparatus of claim 1, wherein the second thermal conducting member comprises a heat sink.

6. The apparatus of claim 1, wherein the channel is defined by the first thermal conducting member and located on the first thermal transfer surface.

7. The apparatus of claim 1, wherein the channel is defined by the first thermal conducting member and located about the perimeter of the first thermal transfer surface.

8. The apparatus of claim 1, wherein the channel is defined by the second thermal conducting member and located on the second thermal transfer surface.

9. The apparatus of claim 1, wherein a sensitive surface is located adjacent the perimeter of the first thermal conducting member, whereby the channel prevents the excess thermal interface material from engaging the sensitive surface.

10. An information handling system, comprising:
an information handling system chassis;
a board coupled to the chassis;
a processor mounted to the board;
a first thermal conducting member thermally coupled to the processor and having a first thermal transfer surface;
a second thermal conducting member having a second thermal transfer surface that is located adjacent the first thermal transfer surface;
a thermal interface material engaging the first thermal transfer surface and the second thermal transfer surface; and
a channel defined adjacent the first thermal transfer surface and the second thermal transfer surface, whereby an excess of the thermal interface material is located in the channel.

11. The system of claim 10, wherein the first thermal conducting member comprises a surface on the processor.

12. The system of claim 10, wherein the first thermal conducting member comprises an integrated heat spreader.

13. The system of claim 10, wherein the first thermal conducting member comprises a die.

14. The system of claim 10, wherein the second thermal conducting member comprises a heat sink.

15. The system of claim 10, wherein the channel is defined by the first thermal conducting member and located on the first thermal transfer surface.

16. The system of claim 10, wherein the channel is defined by the first thermal conducting member and located adjacent the perimeter of the first thermal transfer surface.

17. The system of claim 10, wherein the channel is defined by the second thermal conducting member and located on the second thermal transfer surface.

18. The system of claim 10, wherein a sensitive surface is located adjacent the perimeter of the first thermal conducting member, whereby the channel prevents the excess thermal interface material from engaging the sensitive surface.

19. A method for housing excess thermal interface material in a heat dissipation system, comprising:
providing a heat producing component having a first thermal conducting member thermally coupled to the heat producing component;
engaging a second thermal conducting member with a thermal interface material located on the first thermal conducting member; and
housing excess thermal interface material in a channel defined adjacent the first thermal conducting member and the second thermal conducting member.

20. The method of claim 19, further comprising:
dissipating heat from the heat producing component through the first thermal conducting member, the thermal interface material, and the second thermal conducting member.
